(19) United States
(12) Patent Application Publication
(10) Pub. No.: US 2025/0183621 A1
(43) Pub. Date: Jun. 5, 2025

(54) METHOD OF MANUFACTURING PHOTONIC CRYSTAL AND METHOD OF MANUFACTURING LIGHT-EMITTING DEVICE

(71) Applicant: SEIKO EPSON CORPORATION, Tokyo (JP)

(72) Inventors: Yoshitomo KUMAI, OKAYA-SHI (JP); Toru NIMURA, MATSUMOTO-SHI (JP)

(73) Assignee: SEIKO EPSON CORPORATION, Tokyo (JP)

(21) Appl. No.: 18/964,658

(22) Filed: Dec. 1, 2024

(30) Foreign Application Priority Data
Dec. 4, 2023 (JP) 2023-204467

(51) Int. Cl. H01S 5/183; H01S 5/30

(52) U.S. Cl. CPC H01S 5/18308; H01S 5/3013; H01S 2304/04

(57) ABSTRACT

A method of manufacturing a photonic crystal, wherein a diameter of a first hole is larger than that of a third hole, a diameter of a second hole is larger than that of a fourth hole in a step of forming the holes, a difference between the diameter of the first hole and a diameter of a first low refractive index portion is larger than a difference between the diameter of the third hole and a diameter of a third low refractive index portion, and a difference between the diameter of the second hole and a diameter of a second low refractive index portion is larger than a difference between the diameter of the fourth hole and a diameter of a fourth low refractive index portion in a step of forming the low refractive index portions.

The present application is based on, and claims priority from JP Application Serial Number 2023-204467, filed Dec. 4, 2023, the disclosure of which is hereby incorporated by reference herein in its entirety.

### BACKGROUND

### 1. Technical Field

The present disclosure relates to a method of manufacturing a photonic crystal and a method of manufacturing a light-emitting device.

### 2. Related Art

A photonic crystal that periodically changes in refractive index is known.

For example, JP-A-2012-33706 describes a method of manufacturing a two-dimensional photonic laser including a process of producing a base material layer, a process of periodically forming voids in the base material layer, and a process of epitaxially producing a layer made of AlₓGa₁₋ₓAs on the base material layer and the voids.

In the method of manufacturing the two-dimensional photonic laser as described above, it is required to manufacture a photonic crystal configured to exhibit a stable optical confinement effect.

### SUMMARY

An aspect of a method of manufacturing a photonic crystal according to the present disclosure includes forming a first layer, forming, in the first layer, a first hole, a second hole separated from the first hole by a first distance in a first direction, a third hole separated from the first hole by a second distance larger than the first distance in a second direction intersecting the first direction, and a fourth hole separated from the third hole by a third distance smaller than the second distance in the first direction, and crystal-growing a second layer in the first hole, the second hole, the third hole, and the fourth hole to form a first low refractive index portion having a lower refractive index than the first layer in the first hole, form a second low refractive index portion having a lower refractive index than the first layer in the second hole, form a third low refractive index portion having a lower refractive index than the first layer in the third hole, and form a fourth low refractive index portion having a lower refractive index than the first layer in the fourth hole, wherein in the forming of the first hole, the second hole, the third hole, and the fourth hole, the first hole and the third hole are formed so that a diameter of the first hole is larger than that of the third hole, and the second hole and the fourth hole are formed so that a diameter of the second hole is larger than that of the fourth hole, and in the forming of the first low refractive index portion, the second low refractive index portion, the third low refractive index portion, and the fourth low refractive index portion, the second layer is crystal-grown so that a difference between the diameter of the first hole and a diameter of the first low refractive index portion is larger than a difference between the diameter of the third hole and a diameter of the third low refractive index portion, and a difference between the diameter of the second hole and a diameter of the second low refractive index portion is larger than a difference between the diameter of the fourth hole and a diameter of the fourth low refractive index portion.

An aspect of the method of manufacturing the light-emitting device according to the present disclosure has an aspect of the method of manufacturing the photonic crystal.

### BRIEF DESCRIPTION OF THE DRAWINGS

FIG. 1 is a cross-sectional view schematically illustrating a light-emitting device according to an embodiment.

FIG. 2 is a plan view schematically illustrating the light-emitting device according to the present embodiment.

FIG. 3 is a flowchart illustrating a method of manufacturing a light-emitting device according to the present embodiment.

FIG. 4 is a cross-sectional view schematically illustrating a manufacturing step for the light-emitting device according to the present embodiment.

FIG. 5 is a plan view illustrating a manufacturing process for a light-emitting device according to the present embodiment.

FIG. 6 is a cross-sectional view schematically illustrating a manufacturing step of the light-emitting device according to the present embodiment.

FIG. 7 is a cross-sectional view schematically illustrating a manufacturing step of the light-emitting device according to the present embodiment.

FIG. 8 is a cross-sectional view schematically illustrating a manufacturing step of the light-emitting device according to the present embodiment.

FIG. 9 is a cross-sectional view schematically illustrating a manufacturing step of the light-emitting device according to the present embodiment.

FIG. 10 is a cross-sectional view schematically illustrating a manufacturing step of the light-emitting device according to the present embodiment.

FIG. 11 is a plan view schematically showing a manufacturing process for the light-emitting device according to the present embodiment.

FIG. 12 is a cross-sectional view schematically illustrating a manufacturing step of the light-emitting device according to the present embodiment.

FIG. 13 is a cross-sectional view schematically illustrating a manufacturing step of the light-emitting device according to the present embodiment.

FIG. 14 is a plan view schematically showing the manufacturing process for the light-emitting device according to the present embodiment.

FIG. 15 is a cross-sectional view schematically illustrating a manufacturing step of the light-emitting device according to the present embodiment.

FIG. 16 is a cross-sectional view schematically illustrating a manufacturing process of the light-emitting device according to the embodiment.

FIG. 17 is a cross-sectional view schematically showing the manufacturing process for the light-emitting device according to the present embodiment.

FIG. 18 is a cross-sectional view schematically showing the manufacturing process for a light-emitting device according to the present embodiment.

FIG. 19 is a cross-sectional view schematically showing the manufacturing process for a light-emitting device according to the present embodiment.

FIG. 20 is a cross-sectional view schematically showing a light-emitting device according to a modification example of the present embodiment.

FIG. 21 is a cross-sectional view schematically showing the light-emitting device according to a modification example of the present embodiment.

FIG. 22 illustrates an HAADF-STEM image and a BF-STEM image of a first region.

FIG. 23 illustrates an HAADF-STEM image and a BF-STEM image of a second region.

FIG. 24 illustrates an HAADF-STEM image and a BF-STEM image of a third region.

FIG. 25 illustrates a graph showing a relationship between a diameter of holes, a period of the holes, a diameter of voids, and a thickness of an AlGaAs layer on a side surface of the holes.

### DESCRIPTION OF EMBODIMENTS

A preferred embodiment of the present disclosure is described in detail below with reference to the drawings. Note that the embodiments described below do not unduly limit the content of the present disclosure described in the claims. In addition, not all the configurations described below are essential constituent elements of the present disclosure.

### 1. Light-Emitting Device

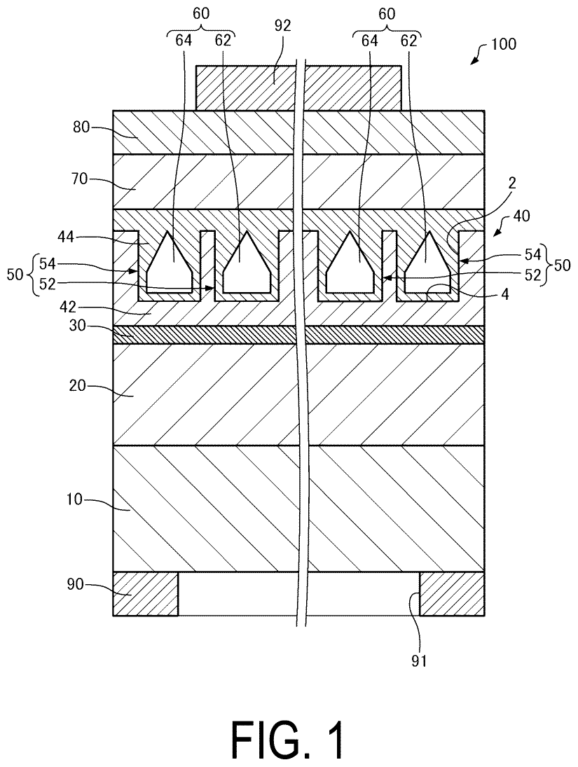

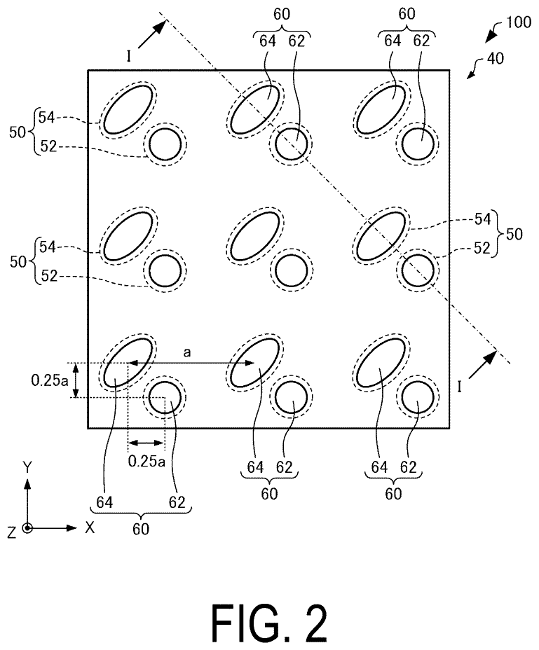

First, a light-emitting device according to the present embodiment will be described with reference to the drawings. FIG. 1 is a cross-sectional view schematically illustrating a light-emitting device 100 according to the present embodiment. FIG. 2 is a plan view schematically illustrating a light-emitting device 100 according to the present embodiment. FIG. 1 is a cross-sectional view taken along line I-I in FIG. 2. Further, in FIG. 2, an X-axis, a Y-axis, and a Z-axis are shown as three mutually orthogonal axes.

As illustrated in FIGS. 1 and 2, the light-emitting device 100 includes, for example, a substrate 10, a first semiconductor layer 20, a light-emitting layer 30, a photonic crystal 40, a second semiconductor layer 70, a contact layer 80, a first electrode 90, and a second electrode 92. For convenience, components other than the photonic crystal 40 are not illustrated in FIG. 2. The light-emitting device 100 is, for example, a photonic crystal surface emitting laser (PCSEL).

The substrate 10 is, for example, a GaAs substrate, or the like. The substrate 10 has, for example, conductivity. The substrate 10 is, for example, transmissive.

The first semiconductor layer 20 is provided at the substrate 10. The first semiconductor layer 20 is provided between the substrate 10 and the light-emitting layer 30. The first semiconductor layer 20 is, for example, an n-type AlGaAs layer doped with Si.

The light-emitting layer 30 is provided on the first semiconductor layer 20. The light-emitting layer 30 is provided between the first semiconductor layer 20 and the second semiconductor layer 70. The light-emitting layer 30 is provided between the first semiconductor layer 20 and the photonic crystal 40. The light-emitting layer 30 generates light when an electric current is injected thereinto. The light-emitting layer 30 includes, for example, a well layer and a barrier layer. The well layer and the barrier layer are i-type semiconductor layers which are not doped with impurities intentionally. The well layer is an InGaAs layer, for example. The barrier layer is a GaAs layer, for example. The light-emitting layer 30 has a multiple quantum well (MQW) structure configured of the well layer and the barrier layer.

Also, the number of well layers and barrier layers forming the light-emitting layer 30 is not particularly limited. For example, only one well layer may be provided, and in this case, the light-emitting layer 30 has a single quantum well (SQW) structure.

The photonic crystal 40 is provided on the light-emitting layer 30. The photonic crystal 40 is provided between the light-emitting layer 30 and the second semiconductor layer 70. A shape of the photonic crystal 40 is, for example, layered. The photonic crystal 40 includes a first layer 42, a second layer 44, and low refractive index portion pairs 60. For convenience, an outer edge of a hole pair 50 and an outer edge of the low refractive index portion pair 60 formed in the photonic crystal 40 are shown in FIG. 2. The hole pair 50 is indicated by a dashed line.

The first layer 42 is provided on the light-emitting layer 30 as illustrated in FIG. 1. The first layer 42 is provided between the light-emitting layer 30 and the second layer 44. The first layer 42 is, for example, a C-doped p-type GaAs layer.

The hole pair 50 is formed in the first layer 42. The hole pair 50 is formed of one hole 52 and the other hole 54. In the example illustrated in FIG. 2, a planar shape of the one hole 52 is a circle. A planar shape of the other hole 54 is an ellipse.

A diameter of the hole 52 is, for example, smaller than that of the hole 54. The diameters of the holes 52 and 54 are, for example, 10 nm or more to 300 nm or less, preferably 20 nm or more to 200 nm or less, and more preferably 40 nm or more to 100 nm or less.

The “diameter of the hole” is a diameter when the planar shape of the hole is a circle, and is a diameter of a minimum bounding circle when the planar shape of the hole is a shape other than a circle. For example, the diameter of the hole is a diameter of a smallest circle that includes a polygon therein when the planar shape of the hole is a polygon, and is a diameter of a smallest circle that includes an ellipse therein when the planar shape of the hole is an ellipse. This is the same for a diameter of a low refractive index portion and a diameter of an opening, which will be described later.

Depths of the holes 52 and 54 are, for example, the same. The depths of the holes 52 and 54 are, for example, 100 nm or more to 500 nm or less, preferably 200 nm or more to 400 nm or less, more preferably 250 nm or more to 350 nm or less, and even more preferably 300 nm. The holes 52 and 54 do not reach the light-emitting layer 30.

A plurality of hole pairs 50 are provided. The plurality of hole pairs 50 are arranged in a square lattice pattern in plan view as illustrated in FIG. 2. The plurality of hole pairs 50 are arranged in a square lattice pattern when viewed in a stacking direction of the first semiconductor layer 20 and the light-emitting layer 30. A pitch of the plurality of hole pairs 50 is, for example, 10 nm or more to 500 nm or less, preferably 100 nm or more to 400 nm or less, and more preferably 200 nm or more to 300 nm or less.

The second layer 44 is provided on the first layer 42 as illustrated in FIG. 1. The second layer 44 is provided between the first layer 42 and the second semiconductor layer 70. The second layer 44 is provided on an upper surface of a convex portion of the first layer 42 formed by the holes 52 and 54.

The second layer 44 is provided in the holes 52 and 54. The second layer 44 is provided on side surfaces 2 and bottom surfaces 4 of the holes 52 and 54. The side surfaces 2 and the bottom surfaces 4 are defined by the first layer 42. A portion provided on the side surface 2 of the second layer 44 has a portion whose thickness gradually increases from the light-emitting layer 30 toward the second semiconductor layer 70. The portion whose thickness gradually increases is located in upper portions of the holes 52 and 54. In the illustrated example, a thickness of the portion provided on the side surface 2 and the bottom surface 4 of the second layer 44 is constant in lower portions of the holes 52 and 54.

Although not shown, the second layer 44 may be provided in the holes 52 and 54, and may not be provided on the upper surface of the convex portion of the first layer 42. In this case, the second layers 44 provided in the holes 52 and 54 are separated from each other.

The second layer 44 is, for example, a group III-V semiconductor layer. The second layer 44 is, for example, a C-doped p-type AlGaAs layer. A composition ratio of Al and Ga in the second layer 44 is, for example, 1:1. For example, a refractive index of the first layer 42 and a refractive index of the second layer 44 are different from each other. The refractive index of the second layer 44 is, for example, lower than the refractive index of the first layer 42. The second layer 44 may be a GaAs layer.

The low refractive index portion pair 60 are provided in the hole pair 50. One low refractive index portion 62 of the low refractive index portion pair 60 is provided in one hole 52 of the hole pair 50. The other low refractive index portion 64 of the low refractive index portion pair 60 is provided in the other hole 54 of the hole pair 50. Shapes of the low refractive index portions 62 and 64 are defined by the second layer 44. The low refractive index portion 62 is a portion of the hole 52 that is not filled with the second layer 44. The low refractive index portion 64 is a portion of the hole 54 that is not filled with the second layer 44. The low refractive index portions 62 and 64 include a portion whose diameter gradually decreases from the light-emitting layer 30 toward the second semiconductor layer 70.

The refractive index of the low refractive index portions 62 and 64 is lower than the refractive index of the first layer 42. The refractive index of the low refractive index portions 62 and 64 is lower than the refractive index of the second layer 44. In the illustrated example, the low refractive index portions 62 and 64 are voids. Although not illustrated, the low refractive index portions 62 and 64 may not be voids and may be formed of materials having a lower refractive index than the first layer 42 and the second layer 44.

A plurality of low refractive index portion pairs 60 are provided. As illustrated in FIG. 2, the plurality of low refractive index portion pairs 60 are arranged in a square lattice in plan view, similar to the plurality of hole pairs 50. A pitch a of the plurality of low refractive index portion pairs 60 is, for example, the same as a wavelength of the light generated in the light-emitting layer 30. In the illustrated example, the pitch a is a distance between centers of the low refractive index portions 62 of the adjacent low refractive index portion pairs 60. The plurality of low refractive index portion pairs 60 form a unit lattice. In the photonic crystal 40, two low refractive index portions 62 and 64 are provided per unit lattice. Although not illustrated, three low refractive index portions may be provided per unit lattice.

In one of the low refractive index portion pairs 60, the low refractive index portion 62 is located 0.25a away from the low refractive index portion 64 in a +X-axis direction. The low refractive index portion 62 is located 0.25a away from the low refractive index portion 64 in a −Y-axis direction. Therefore, when the pitch a is equal to a wavelength λ of light, for example, an optical path difference between light reflected by the low refractive index portion 62 and light reflected by the low refractive index portion 64 for light propagating in the +X-axis direction is λ/2, and evanescent interference occurs. Accordingly, light having a desired wavelength is resonated. The plurality of low refractive index portion pairs 60 form a double-lattice photonic crystal.

The second semiconductor layer 70 is provided on the photonic crystal 40 as illustrated in FIG. 1. The second semiconductor layer 70 is provided on the second layer 44. The second semiconductor layer 70 is provided between the second layer 44 and the contact layer 80. The second semiconductor layer 70 is, for example, a C-doped p-type AlGaAs layer. The first semiconductor layer 20 and the second semiconductor layer 70 are cladding layers having a function of confining light in the light-emitting layer 30. The second semiconductor layer 70 may be provided integrally and continuously with the second layer 44.

In the light-emitting device 100, a pin diode is formed of the p-type second semiconductor layer 70, the p-type first layer 42 and second layer 44, the i-type light-emitting layer 30, and the n-type first semiconductor layer 20. In the light-emitting device 100, when a forward bias voltage of the pin diode is applied between the first electrode 90 and the second electrode 92, a current is injected into the light-emitting layer 30, and recombination of electrons and holes occurs in the light-emitting layer 30. This recombination causes light emission. The light generated in the light-emitting layer 30 propagates in the in-plane direction, forms a standing wave by an effect of the photonic crystal 40, and receives a gain in the light-emitting layer 30. Thus, laser is oscillated. Then, the light-emitting device 100 emits +1st order diffracted light and −1st order diffracted light as laser light in the stacking direction. Light directed to the second electrode 92 side is reflected by the second electrode 92. Thus, the light-emitting device 100 can emit light from the substrate 10 side.

The “in-plane direction” is a direction perpendicular to the stacking direction of the first semiconductor layer 20 and the light-emitting layer 30. Further, although not shown, a reflective layer may be provided between the second semiconductor layer 70 and the contact layer 80. The reflective layer is, for example, a distributed Bragg reflector (DBR) layer. The reflective layer reflects light generated in the light-emitting layer 30 toward the substrate 10.

The contact layer 80 is provided on the second semiconductor layer 70. The contact layer 80 is provided between the second semiconductor layer 70 and the second electrode 92. An impurity concentration of the contact layer 80 is higher than that of the second semiconductor layer 70. The contact layer 80 is, for example, a p-type GaAs layer doped with C.

The first electrode 90 is provided under the substrate 10. The substrate 10 may be in ohmic contact with the first electrode 90. The first electrode 90 is electrically coupled to the first semiconductor layer 20 via the substrate 10. A material of the first electrode 90 is, for example, a metal such as Au, Ge, or Ni, or an alloy thereof. The first electrode 90 is one electrode for injecting a current into the light-emitting layer 30.

An opening 91 formed in the first electrode 90. The opening 91 penetrates the first electrode 90. The opening 91 overlaps the second electrode 92 in plan view. Light generated in the light-emitting layer 30 is emitted through the opening 91.

The second electrode 92 is provided on the contact layer 80. The contact layer 80 may be in ohmic contact with the second electrode 92. The second electrode 92 is electrically coupled to the second semiconductor layer 70 via the contact layer 80. A planar shape of the second electrode 92 is, for example, a square. A material of the second electrode 92 is, for example, a metal such as Au, Ge, or Ni, or an alloy thereof. The second electrode 92 is the other electrode for injecting a current into the light-emitting layer 30.

The light-emitting device 100 is applied to, for example, a laser processing device. Examples of the laser processing device may include a metal 3D printer using selective laser melting (SLM), a laser cleaner using laser light to remove rust or the like from metal, and a laser annealing device using laser light to heat a surface of metal or resin. The light-emitting device 100 is further applied to, for example, a Light Detection and Ranging (LiDAR) sensing system for automated driving of an automobile or autonomous traveling of a robot.

### 2. Method of Manufacturing Light-Emitting Device

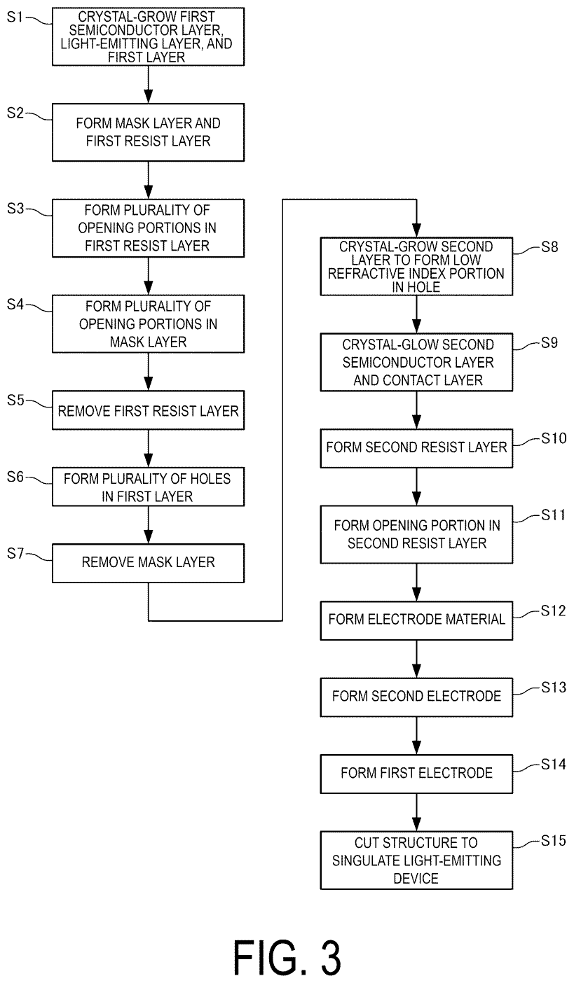

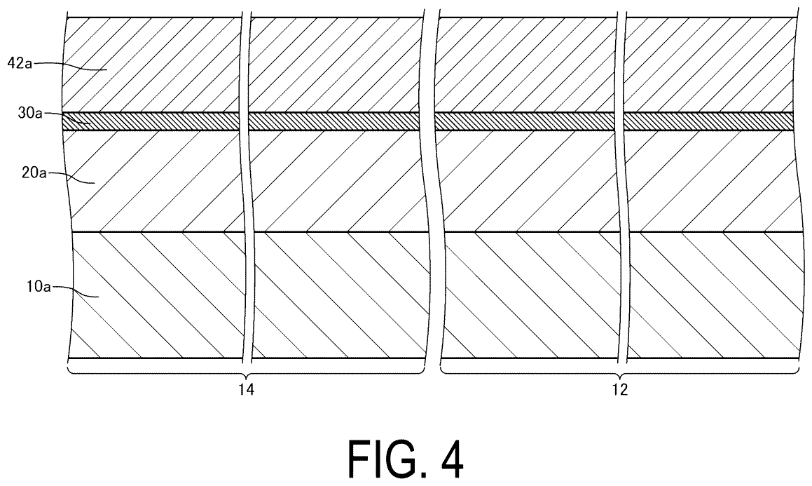

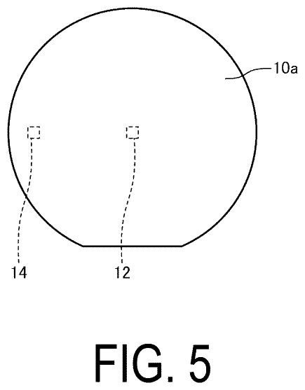

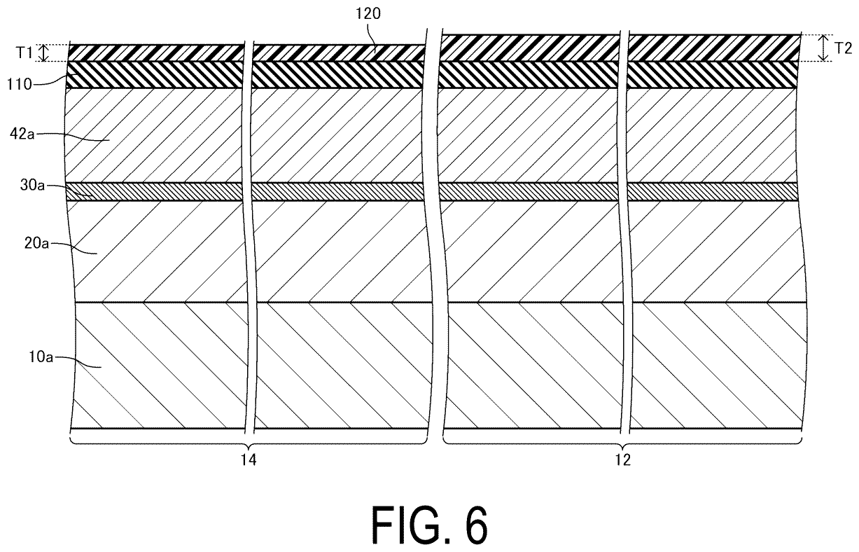

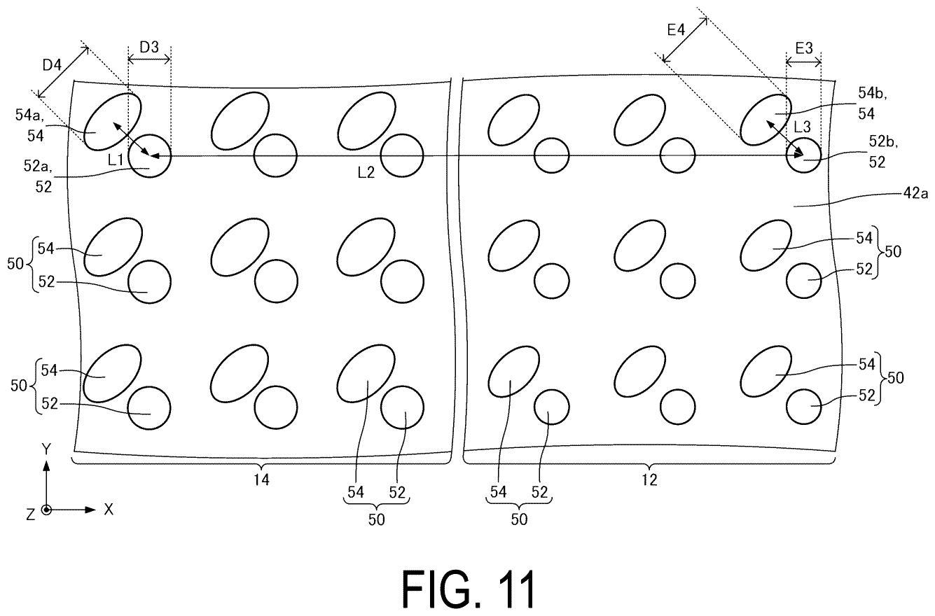

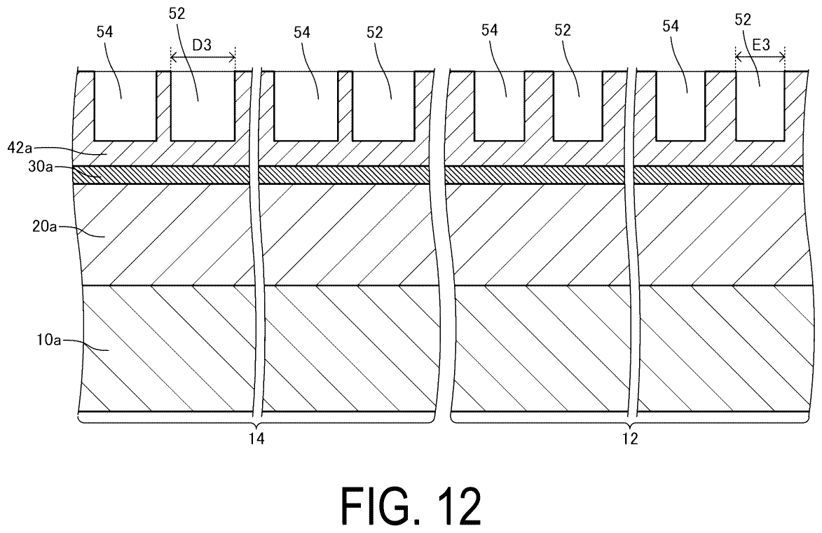

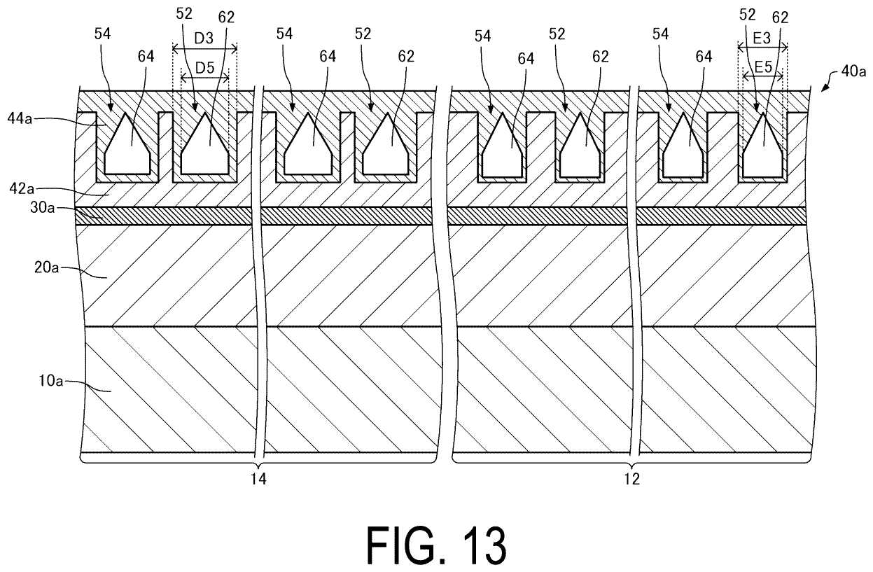

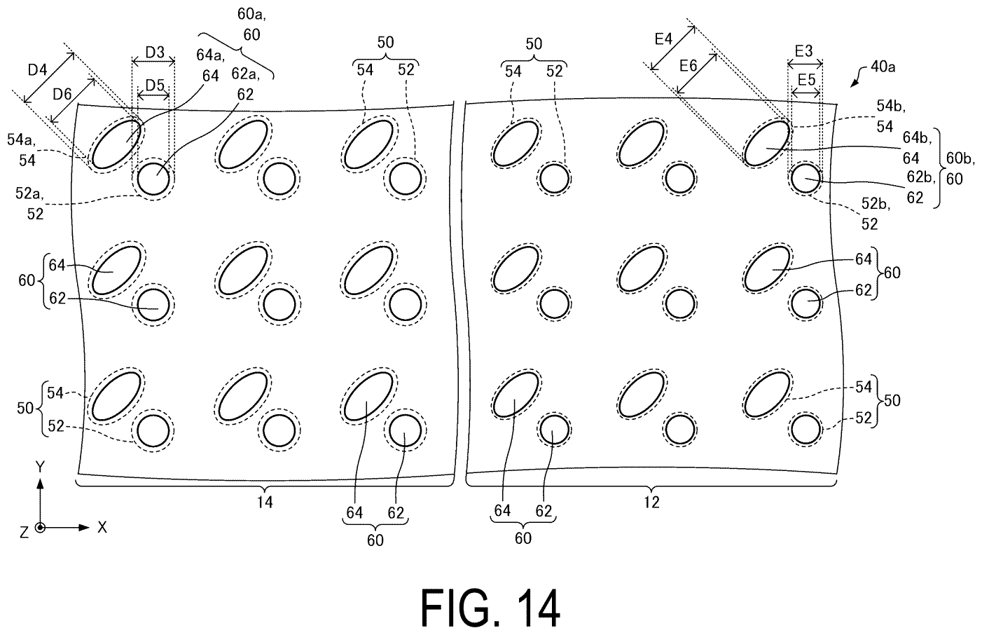

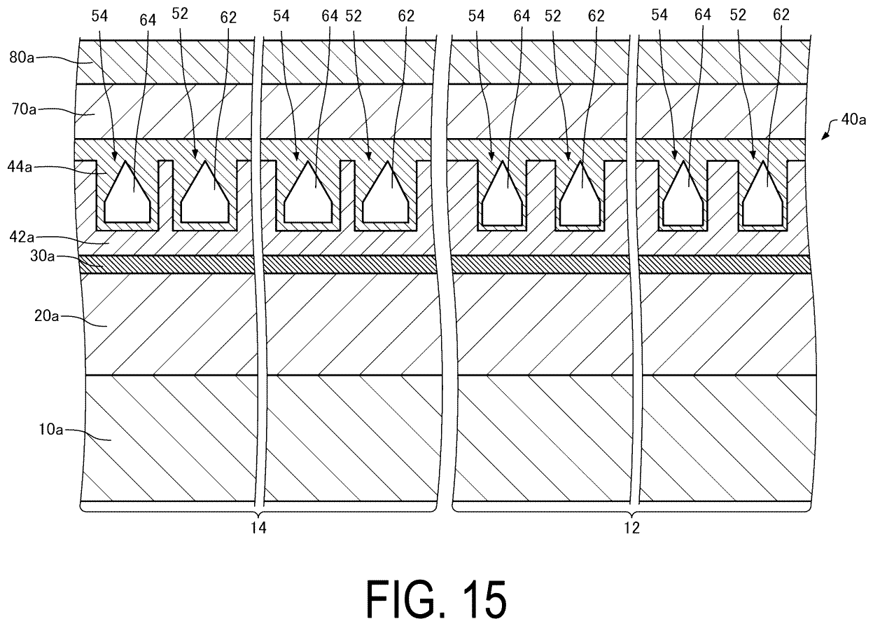

Next, a method of manufacturing the light-emitting device 100 according to the present embodiment will be described with reference to the drawings. FIG. 3 is a flowchart illustrating a method of manufacturing the light-emitting device 100 according to the present embodiment. FIG. 4 is a cross-sectional view schematically illustrating a step of manufacturing the light-emitting device 100 according to the present embodiment. FIG. 5 is a plan view schematically showing a manufacturing process for the light-emitting device 100 according to the present embodiment. FIGS. 6 to 10 are cross-sectional views schematically illustrating a manufacturing process for the light-emitting device 100 according to the present embodiment. FIG. 11 is a plan view schematically illustrating the manufacturing process for the light-emitting device 100 according to the present embodiment. FIGS. 12 and 13 are cross-sectional views schematically illustrating a manufacturing process for the light-emitting device 100 according to the present embodiment. FIG. 14 is a plan view schematically illustrating the manufacturing process for the light-emitting device 100 according to the present embodiment. FIGS. 15 to 19 are cross-sectional views schematically illustrating a manufacturing process for the light-emitting device 100 according to the present embodiment.

As illustrated in FIGS. 3 and 4, a first semiconductor layer 20a, a light-emitting layer 30a, and a first layer 42a are crystal-grown in this order on the substrate 10a (step S1). Specifically, the first semiconductor layer 20a, the light-emitting layer 30a, and the first layer 42a are epitaxially grown by a metal organic chemical vapor deposition (MOCVD) method.

The substrate 10a, the first semiconductor layer 20a, the light-emitting layer 30a, and the first layer 42 are cut in step S15 to be described later to become the substrate 10, the first semiconductor layer 20, the light-emitting layer 30, and the first layer 42 illustrated in FIG. 1, respectively.

The substrate 10a is, for example, a wafer as illustrated in FIG. 5. In a plan view, the substrate 10a includes a central portion 12 including a center, and a peripheral portion 14 located in the periphery. The central portion 12 and the peripheral portion 14 are spaced apart from each other. A distance between the central portion 12 and the peripheral portion 14 is, for example, larger than one third of a diameter of the wafer. In FIGS. 4 and 6 to 19, the central portion 12 and the peripheral portion 14 of the substrate 10a are shown.

As illustrated in FIG. 6, a mask layer 110 is formed at the first layer 42a, and a first resist layer 120 is formed at the mask layer 110 (step S2). The mask layer 110 is formed, for example, by a plasma Chemical Vapor Deposition (CVD) method. The mask layer 110 is, for example, a silicon nitride layer. The first resist layer 120 is formed, for example, by a spin coating method.

In the substrate 10a, for example, warpage occurs due to heat in the process (step S1) of crystal-growing the first semiconductor layer 20a, the light-emitting layer 30a, and the first layer 42a. Therefore, for example, as illustrated in FIG. 6, a thickness T1 of the first resist layer 120 in the peripheral portion 14 is smaller than a thickness T2 of the first resist layer 120 in the central portion 12.

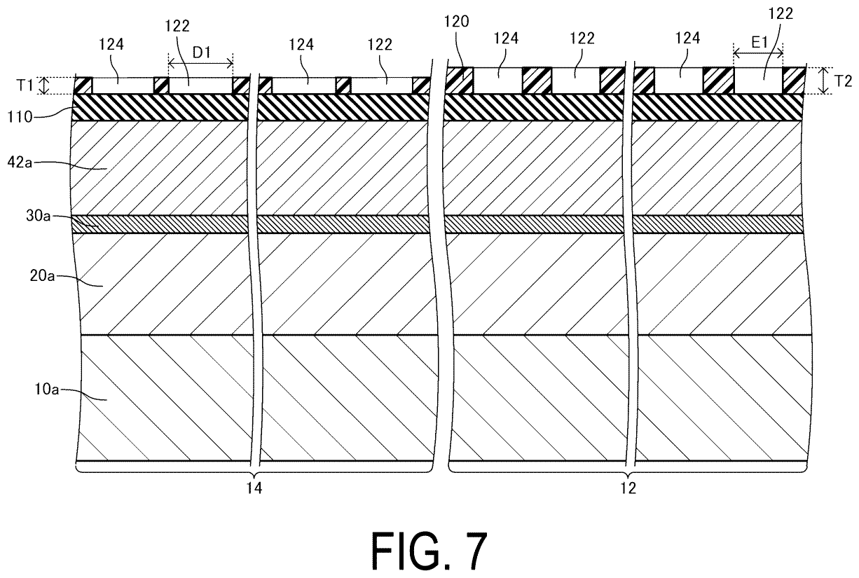

As illustrated in FIG. 7, a plurality of openings 122 and 124 are formed in the first resist layer 120 (step S3). The openings 122 and 124 are formed by using exposure and development. The exposure may be performed using an electron beam drawing apparatus. The openings 122 are openings for forming the holes 52. The openings 124 are openings for forming the holes 54. Since the thickness T1 of the first resist layer 120 in the peripheral portion 14 is smaller than the thickness T2 of the first resist layer 120 in the central portion 12, a diameter D1 of the opening 122 in the peripheral portion 14 is larger than a diameter E1 of the opening 122 in the central portion 12. Similarly, the diameter of the opening 124 in the peripheral portion 14 is larger than the diameter of the opening 124 in the central portion 12. The openings 122 and 124 may be formed by a nanoimprint method.

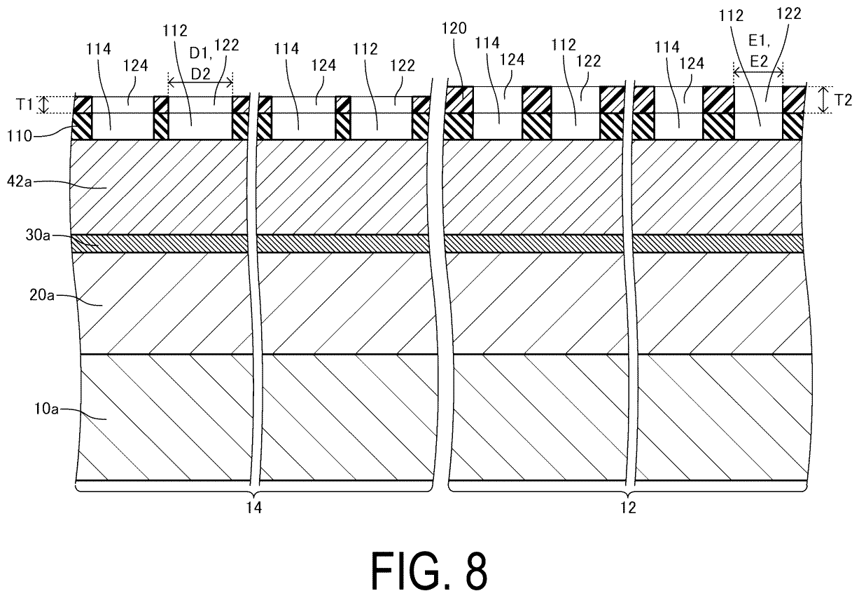

As illustrated in FIG. 8, the mask layer 110 is etched using the first resist layer 120 as a mask so that a plurality of openings 112 and 114 are formed in the mask layer 110 (step S4). The etching is, for example, dry etching using a fluorine-based gas. The opening 112 is an opening that overlaps the opening 122 in plan view. The opening 114 is an opening that overlaps the opening 124 in plan view. Since a diameter D1 of the opening 122 in the peripheral portion 14 is larger than the diameter E1 of the opening 122 in the central portion 12, a diameter D2 of the opening 112 in the peripheral portion 14 is larger than the diameter E2 of the opening 112 in the central portion 12. Similarly, a diameter of the opening 114 in the peripheral portion 14 is larger than a diameter of the opening 114 in the central portion 12. In the illustrated example, the diameters D1 and D2 are the same. The diameters E1 and E2 are the same.

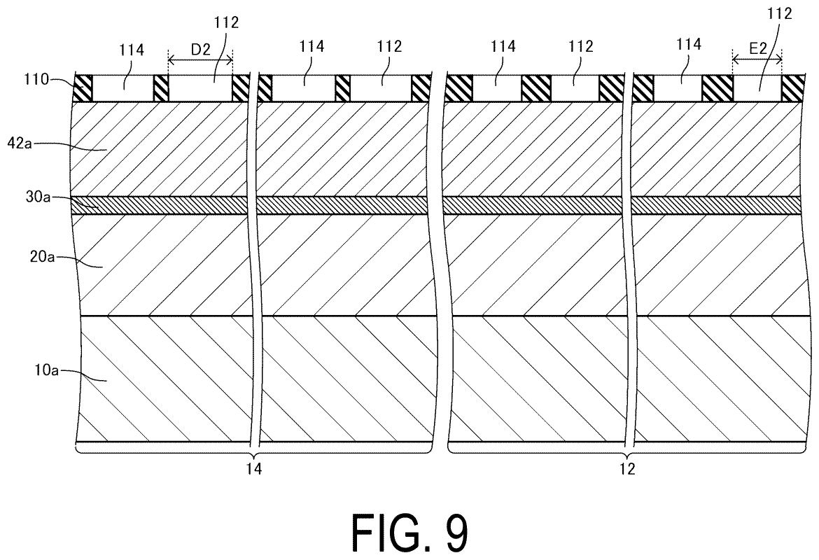

As illustrated in FIG. 9, the first resist layer 120 is removed (step S5). The first resist layer 120 is removed by, for example, ashing.

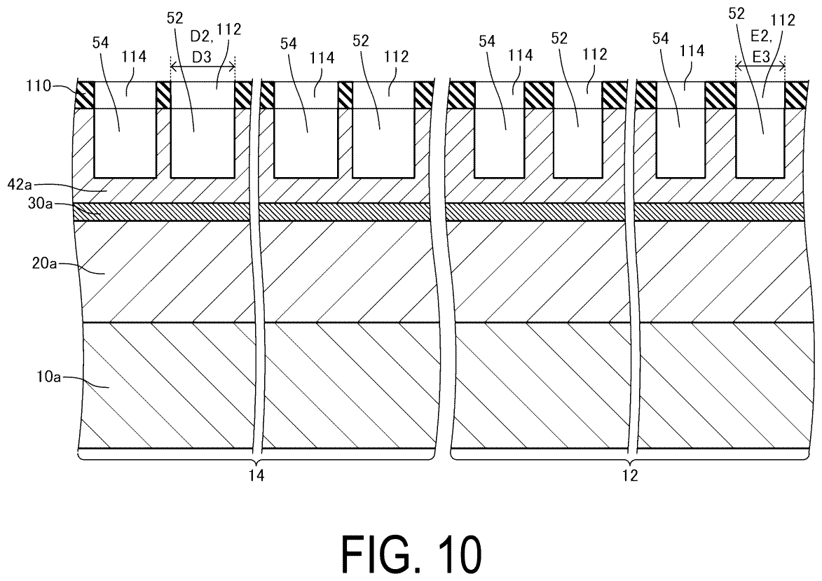

As illustrated in FIG. 10, the first layer 42a is etched using the mask layer 110 as a mask so that a plurality of holes 52 and 54 are formed in the first layer 42a (step S6). The etching is, for example, dry etching using a chlorine-based gas.

In this process, as illustrated in FIG. 11, the hole 52 is formed so that a diameter D3 of the hole 52 in the peripheral portion 14 is larger than a diameter E3 of the hole 52 in the central portion 12. Further, the holes 54 in the peripheral portion 14 are formed so that a diameter D4 of the holes 54 is larger than a diameter E4 of the holes 54 in the central portion 12. Since a diameter D3 of the opening 112 in the peripheral portion 14 is larger than the diameter E3 of the opening 112 in the central portion 12, the diameter D3 of the hole 52 in the peripheral portion 14 is larger than the diameter E3 of the hole 52 in the central portion 12. Similarly, the diameter D4 of the hole 54 in the peripheral portion 14 is larger than the diameter E4 of the hole 54 in the central portion 12. In the example illustrated in FIG. 10, the diameters D2 and D3 are the same. The diameters E2 and E3 are the same.

As illustrated in FIG. 11, a first hole 52a among the plurality of holes 52 is the hole 52 provided in the peripheral portion 14 and is, for example, the hole 52 located at the outermost periphery among the plurality of holes 52. The second hole 54a of the plurality of holes 54 is the hole 54 provided in the peripheral portion 14 and is, for example, the hole 54 located at the outermost periphery among the plurality of holes 54. Among the plurality of holes 52, the third hole 52b is the hole 52 provided in the central portion 12 and is, for example, the hole 52 closest to the center of the substrate 10a. Among the plurality of holes 54, a fourth hole 54b is the hole 54 provided in the central portion 12 and is, for example, the hole 54 closest to the center of the substrate 10a.

The second hole 54a is formed at a first distance L1 from the first hole 52a in the first direction. The third hole 52b is formed at a second distance L2 from the first hole 52a in the second direction. The fourth hole 54b is formed at a third distance L3 from the third hole 52b in the first direction. In the illustrated example, the first direction is a direction inclined by 45° with respect to a −X-axis direction and a +Y-axis direction when viewed from the Z-axis direction. The second direction is a direction intersecting the first direction, and is the +X-axis direction.

The first distance L1 a distance between a center of the first hole 52a and a center of the second hole 54a. The second distance L2 a distance between a center of the first hole 52a and a center of the third hole 52b. The second distance L2 is larger than the first distance L1. The third distance L3 a distance between a center of the third hole 52b and a center of the fourth hole 54b. The third distance L3 is smaller than the second distance L2. In the illustrated example, the first distance L1 and the third distance L3 are the same. The fourth hole 54b is formed at a distance of the third distance L3 from the second hole 54a in the +X-axis direction.

As illustrated in FIG. 12, the mask layer 110 is removed (step S7). The mask layer 110 is removed by, for example, wet etching. Next, a surface of the first layer 42a is cleaned by thermal cleaning or the like.

As illustrated in FIG. 13, a second layer 44a is crystal-grown in the holes 52 and 54, the low refractive index portion 62 is formed in the hole 52, and the low refractive index portion 64 is formed in the hole 54 (step S8). Concretely, the second layer 44a is epitaxially grown by the MOCVD method. The second layer 44a is formed at the first layer 42a. Through this process, a photonic crystal 40a is formed. The second layer 44a and the photonic crystal 40a are cut in step S15 described later to become the second layer 44 and the photonic crystal 40 illustrated in FIG. 1, respectively.

A growth temperature of the second layer 44a is, for example, from 550° C. to 650° C., preferably from 570° C. to 640° C., and more preferably from 600° C. to 625° C. In the crystal-growth of the second layer 44a, a first gas for supplying a group III element and a second gas for supplying a group V element are used. The first gas contains, for example, trimethyl gallium (TMG) which is a raw material of Ga and trimethyl aluminum (TMA) which is a raw material of Al. The second gas contains, for example, tert-butylarsine (TBA) which is a raw material of As. A ratio of a flow rate of the second gas to a flow rate of the first gas is, for example, from 10 to 30, is preferably from 15 to 25, and is more preferably from 17 to 23.

In this process, the flow rates of the first gas and the second gas supplied to the hole 52 are lower than the flow rates of the first gas and the second gas supplied to an upper side of the hole 52. Therefore, a growth rate in a lateral direction of the second layer 44a in the hole 52 is lower than that of the second layer 44a above the hole 52. Accordingly, the upper side of the hole 52 is first blocked by the second layer 44a. Thus, the first gas and the second gas are not supplied to the hole 52. As a result, the low refractive index portion 62, which is a void, is formed. The same applies to the low refractive index portion 64 provided in the hole 54.

In this process, as illustrated in FIG. 14, the crystal growth of the second layer 44a is grown so that a difference between the diameter D3 of the hole 52 in the peripheral portion 14 and the diameter D5 of the low refractive index portion 62 in the peripheral portion 14 is larger than a difference between the diameter E3 of the hole 52 in the central portion 12 and the diameter E5 of the low refractive index portion 62 in the central portion 12. Further, the crystal growth of the second layer 44a is grown so that a difference between the diameter D4 of the hole 54 in the peripheral portion 14 and the diameter D6 of the low refractive index portion 64 in the peripheral portion 14 is larger than a difference between the diameter E4 of the hole 54 in the central portion 12 and the diameter E6 of the low refractive index portion 64 in the central portion 12.

In the present process, the upper side of the hole 52 in the peripheral portion 14 is blocked by the second layer 44a later than the upper side of the hole 52 in the central portion 12. That is, at a point in time when the upper side of the hole 52 in the central portion 12 is blocked by the second layer 44a, the upper side of the hole 52 in the peripheral portion 14 has not yet been blocked by the second layer 44a. Therefore, a large amount of the first gas and the second gas is supplied to the hole 52 in the peripheral portion 14 than to the hole 52 in the central portion 12. Thus, it is possible to make a difference between the diameter D3 and the diameter D5 larger than a difference between the diameter E3 and the diameter E5 by creating a shadow effect in which a large amount of gas is supplied to the hole 52 with a larger diameter. The same is applied to the hole 54.

Among the plurality of low refractive index portions 62, the first low refractive index portion 62a is the low refractive index portion 62 provided in the first hole 52a. Among the plurality of low refractive index portions 64, the second low refractive index portion 64a is the low refractive index portion 64 provided in the second hole 54a. Among the plurality of low refractive index portions 62, the third low refractive index portion 62b is the low refractive index portion 62 provided in the third hole 52b. Among the plurality of low refractive index portions 64, the fourth low refractive index portion 64b is the low refractive index portion 64 provided in the fourth hole 54b.

The first low refractive index portion 62a and the second low refractive index portion 64a form a first low refractive index portion pair 60a among the plurality of low refractive index portion pairs 60. The third low refractive index portion 62b and the fourth low refractive index portion 64b form a second low refractive index portion pair 60b among the plurality of low refractive index portion pairs 60.

In the illustrated example, the diameter D3 is a maximum width of the hole 52a. The diameter E3 is a maximum width of the hole 52b. The diameter D4 is a maximum width of the hole 54a. The diameter E4 is a maximum width of the hole 54b. The diameter D5 is a maximum width of the low refractive index portion 62a. The diameter E5 is a maximum width of the low refractive index portion 62b. The diameter D6 is a maximum width of the low refractive index portion 64a. The diameter E6 is a maximum width of the low refractive index portion 64b. The diameter D5 is smaller than the diameter D3. The diameter E5 is smaller than the diameter E3. The diameter D6 is smaller than the diameter D4. The diameter E6 is smaller than the diameter E4.

The diameters D1 to D6 and the diameters E1 to E6 are measured, for example, by a transmission electron microscope (TEM) or a scanning electron microscope (SEM).

As illustrated in FIG. 15, a second semiconductor layer 70a and a contact layer 80a are crystal-grown in this order on the second layer 44a (step S9). Specifically, the second semiconductor layer 70a and the contact layer 80a are epitaxially grown by a MOCVD method. The second semiconductor layer 70a and the contact layer 80a are cut in step S15, which will be described later, to become the second semiconductor layer 70 and the contact layer 80 illustrated in FIG. 1, respectively.

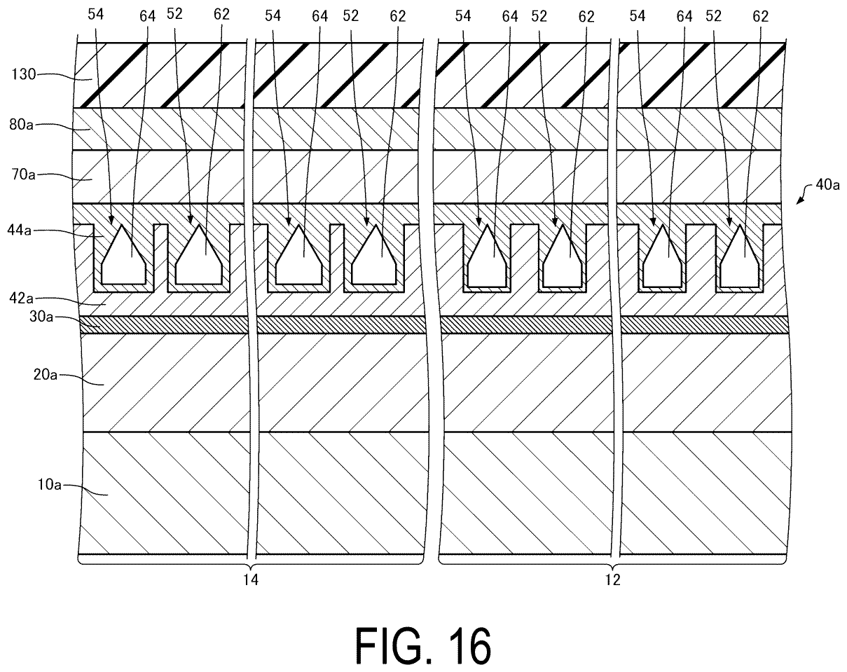

As illustrated in FIG. 16, a second resist layer 130 is formed at the contact layer 80a (step S10). The second resist layer 130 is formed, for example, by a spin coating method. Although not shown, a thickness of the second resist layer 130 in the peripheral portion 14 may be smaller than that of the second resist layer 130 in the central portion 12.

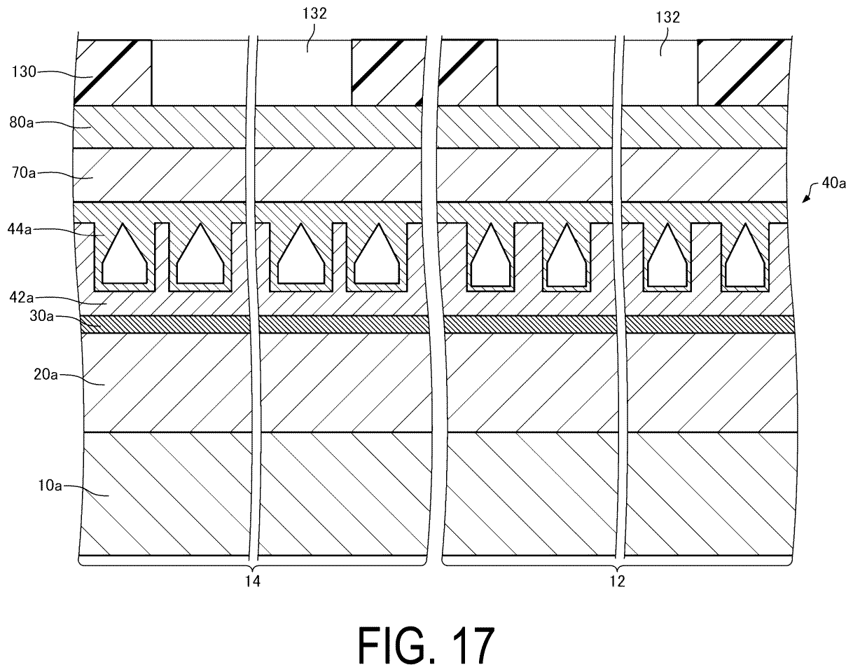

As illustrated in FIG. 17, an opening 132 is formed in the second resist layer 130 (step S11). The opening 132 is formed by exposure and development. The exposure may be performed using an electron beam drawing apparatus.

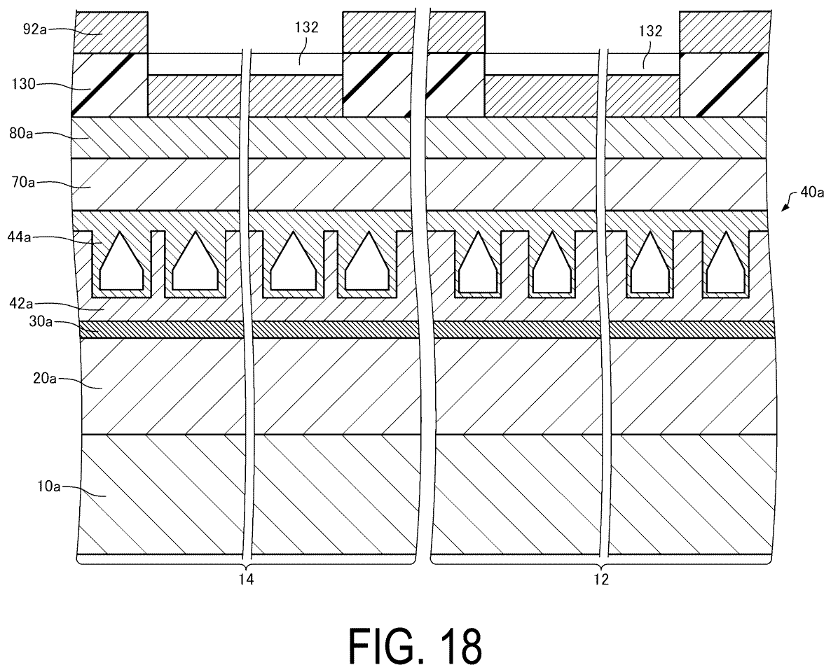

As illustrated in FIG. 18, an electrode material 92a that becomes the second electrode 92 is formed at the contact layer 80a and the second resist layer 130 (step S12). The electrode material 92a is formed by, for example, a vacuum deposition method or a sputtering method.

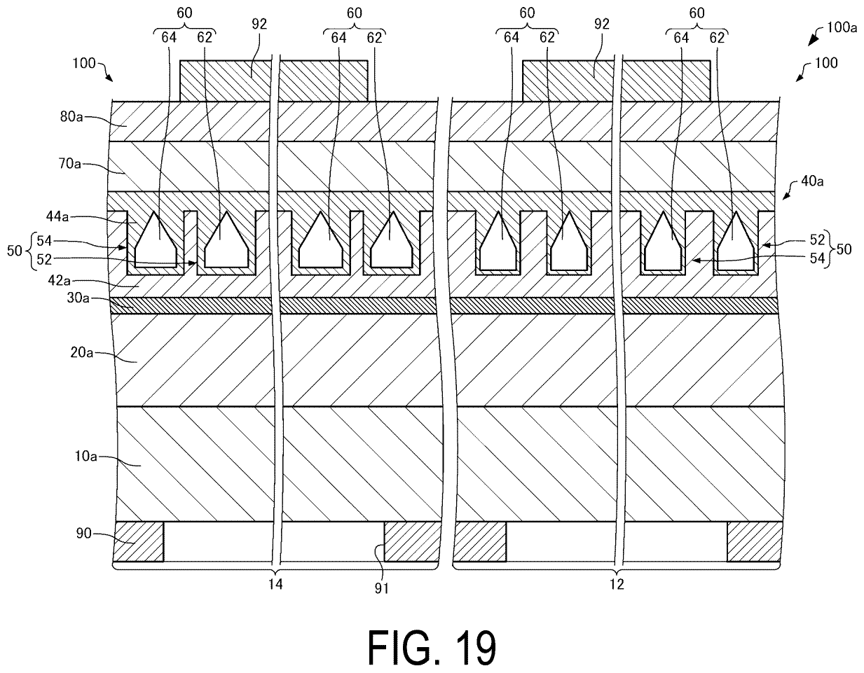

As illustrated in FIG. 19, the second resist layer 130 is removed, and the second electrode 92 is formed by a lift-off method (step S13).

Next, the first electrode 90 is formed under the substrate 10 (step S14). The first electrode 90 is formed by, for example, a vacuum deposition method after a lower surface of the substrate 10 is mirror-polished. Then, the first electrode 90 is patterned so that the opening 91 is formed. The patterning is performed by, for example, photolithography and etching.

A structure 100a including a plurality of the light-emitting devices 100 can be manufactured through the above processes.

Next, the structure 100a is cut to singulate the light-emitting device 100 (step S15). Examples of a cutting method include blade dicing and laser dicing.

The light-emitting device 100 illustrated in FIG. 1 can be manufactured through the above processes.

### 3. Actions and Effects

The method of manufacturing the photonic crystal 40a includes a step of forming a first layer 42a, and a step of forming, in the first layer 42a, a first hole 52a, a second hole 54a separated from the first hole 52a by a first distance L1 in a first direction, a third hole 52b separated from the first hole 52a by a second distance L2 larger than the first distance L1 in a second direction intersecting the first direction, and a fourth hole 54b separated from the third hole 52b by a third distance L3 smaller than the second distance L2 in the first direction. Further, the method of manufacturing the photonic crystal 40a includes a step of growing a second layer 44a in the first hole 52a, the second hole 54a, the third hole 52b, and the fourth hole 54b, a step of forming a first low refractive index portion 62a having a lower refractive index than the first layer 42a in the first hole 52a, forming a second low refractive index portion 64a having a lower refractive index than the first layer 42a in the second hole 54a, forming a third low refractive index portion 62b having a lower refractive index than the first layer 42a in the third hole 52b, and forming a fourth low refractive index portion 64b having a lower refractive index than the first layer 42a in the fourth hole 54b. In the process of forming the first hole 52a, the second hole 54a, the third hole 52b, and the fourth hole 54b, the first hole 52a and the third hole 52b are formed so that a diameter D3 of the first hole 52a is larger than a diameter E3 of the third hole 52b, and the second hole 54a and the fourth hole 54b are formed so that a diameter D4 of the second hole 54a is larger than a diameter E4 of the fourth hole 54b. In a step of forming the first low refractive index portion 62a, the second low refractive index portion 64a, the third low refractive index portion 62b, and the fourth low refractive index portion 64b, the second layer 44a is crystal-grown so that a difference between the diameter D3 of the first hole 52a and a diameter D5 of the first low refractive index portion 62a is larger than a difference between the diameter E3 of the third hole 52b and a diameter E5 of the third low refractive index portion 62b, and a difference between the diameter D4 of the second hole 54a and a diameter D6 of the second low refractive index portion 64a is larger than a difference between the diameter E4 of the fourth hole 54b and a diameter E6 of the fourth low refractive index portion 64b.

Therefore, in the method of manufacturing the photonic crystal 40a, it is possible to make the difference between the diameter D5 of the first low refractive index portion 62a and the diameter E5 of the third low refractive index portion 62b smaller than that when the difference between the diameter D3 and the diameter D5 is the same as the difference between the diameter E3 and the diameter E5 in the crystal growth of the second layer, for example. Further, it is possible to make a difference between the diameter D6 of the second low refractive index portion 64a and the diameter E6 of the fourth low refractive index portion 64b smaller than that when a difference between the diameter D4 and the diameter D6 is the same as the difference between the diameter E4 and the diameter E6 in the crystal growth of the second layer, for example. Accordingly, variations in an optical confinement coefficient can be reduced. Therefore, it is possible to manufacture the photonic crystal 40a capable of exhibiting a stable optical confinement effect.

In the method of manufacturing the photonic crystal 40a, the diameter D3 of the first hole 52a is smaller than the diameter D4 of the second hole 54a, and the diameter E3 of the third hole 52b is smaller than the diameter E4 of the fourth hole 54b. Therefore, in the method of manufacturing the photonic crystal 40a, it is possible to increase the asymmetry in the unit lattice and strengthen the radiation of light in a vertical direction.

In the method of manufacturing the photonic crystal 40a, the first low refractive index portion 62a and the second low refractive index portion 64a form the first low refractive index portion pair 60a, the third low refractive index portion 62b and the fourth low refractive index portion 64b form the second low refractive index portion pair 60b, and the first low refractive index portion pair 60a and the second low refractive index portion pair 60b form a unit lattice. Therefore, in the method of manufacturing the photonic crystal 40a, the photonic crystal 40a having a double unit lattice can be formed.

In the method of manufacturing the photonic crystal 40a, a refractive index of the first layer 42a and a refractive index of the second layer 44a are different from each other. Therefore, in the method of manufacturing the photonic crystal 40a, it is easy to adjust a refractive index of the photonic crystal 40a.

In the method of manufacturing the photonic crystal 40a, the second layer 44a is crystal-grown by the MOCVD method. Therefore, in the method of manufacturing the photonic crystal 40a, the shadow effect can be exhibited during the crystal growth of the second layer 44a.

In the method of manufacturing the photonic crystal 40a, the growth temperature of the second layer 44a is from 550° C. to 650° C. Therefore, in the method of manufacturing the photonic crystal 40a, the shadow effect can be exhibited during the crystal growth of the second layer 44a. Furthermore, since the growth temperature of the second layer 44a is equal to or larger than 550° C., crystal defects are less likely to occur in the second layer 44a. Further, since the growth temperature of the second layer 44a is 650° C. or lower, it is difficult for shapes of the holes 52a, 52b, 54a, and 54b to be distorted by heat.

In the method of manufacturing the photonic crystal 40a, the second layer 44a is the group III-V semiconductor layer, and the ratio of the flow rate of the second gas for supplying the group V element to the flow rate of the first gas for supplying the group III element is from 10 to 30 in the crystal growing of the second layer 44a, therefore, in the method of manufacturing the photonic crystal 40a, the shadow effect can be exhibited in the crystal growing of the second layer 44a.

In the method of manufacturing the photonic crystal 40a, the first low refractive index portion 62a, the second low refractive index portion 64a, the third low refractive index portion 62b, and the fourth low refractive index portion 64b are voids. Therefore, in the method of manufacturing the photonic crystal 40a, it is possible to reduce the refractive indexes of the low refractive index portions 62a, 62b, 64b, and 64b.

In the crystal growth of the second layer, the upper sides of the first hole 52a, the second hole 54a, the third hole 52b, and the fourth hole 54b are blocked by the second layer 44a, so that the first gas and the second gas are not supplied to the first hole 52a, the second hole 54a, the third hole 52b, and the fourth hole 54b, a void is formed, and the upper side of the first hole 52a is blocked later than the upper side of the third hole 52b, and the upper side of the second hole 54a is blocked later than the upper side of the fourth hole 54b. Therefore, in the method of manufacturing the photonic crystal 40, it is possible to make the difference between the diameter D3 of the first hole 52a and the diameter D5 of the first low refractive index portion 62a larger than the difference between the diameter E3 of the third hole 52b and the diameter E5 of the third low refractive index portion 62b. Further, it is possible to make the difference between the diameter D4 of the second hole 54a and the diameter D6 of the second low refractive index portion 64a larger than the difference between the diameter E4 of the fourth hole 54b and the diameter E6 of the fourth low refractive index portion 64b.

The method of manufacturing the light-emitting device 100 includes the method of manufacturing the photonic crystal 40a. As described above, in the method of manufacturing the photonic crystal 40a, the variations in the optical confinement factor can be reduced. As indicated Formula (1) described below, an optical confinement factor F affects a threshold current density Jₜₕ. Therefore, in the method of manufacturing the light-emitting device 100, variations in the threshold current density Jₜₕ can be reduced.

$$\begin{matrix}[ Math 1 ] & \\ {J}_{th} = \frac{{J}_{0} d}{{η}_{spon}} + \frac{{J}_{0} d}{{g}_{0} {η}_{spon} Γ} ( {α}_{int} + {α}_{//} + ( 1 + \sqrt{R} cos θ ) {α}_{⊥} ) & ( 1 )\end{matrix}$$

$$g = \frac{{g}_{0}}{{J}_{0}} ( {J}_{nom} - {J}_{0} ) \qquad ( 2 )$$

In Formula (1), J₀ and g₀ are fixed values. ηₛₚₒₙ is an internal quantum efficiency during spontaneous emission. d is a thickness of the light-emitting layer 30. αᵢₙₜ is an internal loss. α_{//} is an in-plane loss. α_{⊥} is a radiative loss. R is a power reflectivity. θ is a phase shift. g is a gain, and is expressed by Formula (2) described above. In Formula (2), Jₙₒₘ is a normalized current density.

An example in which the first hole and the second hole are holes in the peripheral portion 14, and the third hole and the fourth hole are holes in the central portion 12 has been described above, but positions of the first hole, the second hole, the third hole, and the fourth hole in plan view are not particularly limited as long as the diameter of the first hole is larger than the diameter of the third hole and the diameter of the second hole is larger than the diameter of the fourth hole.

Further, although an example in which the diameters of the first hole, the second hole, the third hole, and the fourth hole are caused by a thickness of the first resist layer 120 has been described above, the diameters of the first hole, the second hole, the third hole, and the fourth hole may be caused by other conditions rather than the thickness of the first resist layer 120 as long as the diameter of the first hole is larger than that of the third hole and the diameter of the second hole is larger than that of the fourth hole.

### 4. Modification Example of Light-Emitting Device

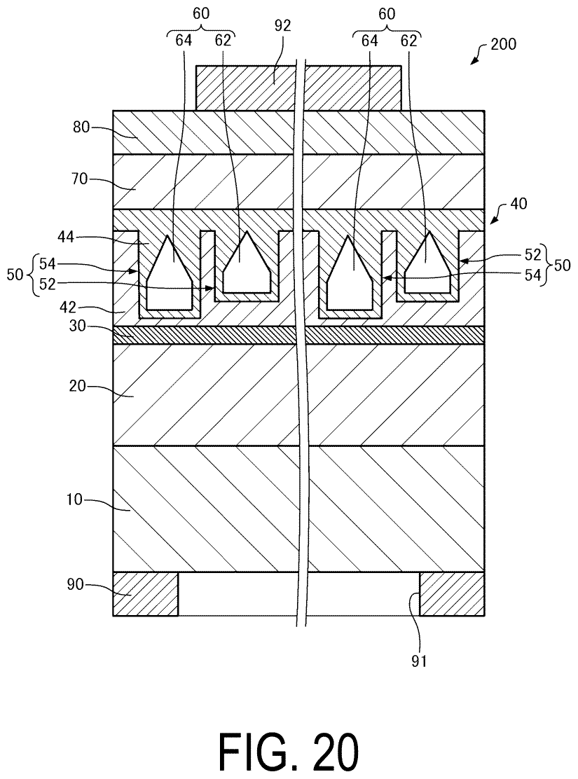

Next, a light-emitting device according to a modification example of the present embodiment will be described with reference to the drawings. FIG. 20 is a cross-sectional view schematically showing a light-emitting device 200 according to a modification example of the present embodiment. Hereinafter, in the light-emitting device 200 according to the modification example of the present embodiment, members having the same functions as constituent members of the light-emitting device 100 according to the above-described embodiment are denoted by the same reference numerals, and detailed description thereof will be omitted.

In the above-described light-emitting device 100, the depths of the holes 52 and 54 are the same, as illustrated in FIG. 1.

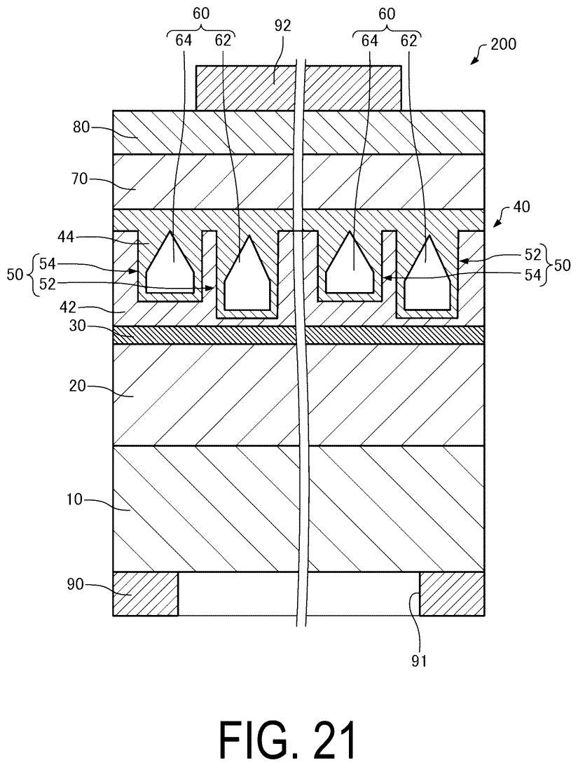

On the other hand, in the light-emitting device 200, the hole 52 is shallower than the hole 54, as illustrated in FIG. 20. It is possible to change depths of the holes 52 and 54 by changing an etching time when forming the holes 52 and 54. As illustrated in FIG. 21, the hole 52 may be deeper than the hole 54.

### 5. Experimental Examples

### 5.1. Sample Preparation

A GaAs layer was crystal-grown at a GaAs substrate by an MOCVD method. Next, a SiN layer was formed at the GaAs layer by a plasma CVD method. Next, a resist layer was formed at the SiN layer by a spin coating method. Next, the resist layer was exposed by an electron beam drawing apparatus and was further developed. Next, the SiN layer was dry-etched with a fluorine-based gas using the resist layer as a mask. Next, the resist layer was removed by ashing. Next, by using the SiN layer as a mask, the GaAs layer was dry-etched with a chlorine-based gas to form a plurality of holes at the GaAs layer. Next, the SiN layer was removed by wet etching. Next, a surface of the GaAs layer was cleaned by thermal cleaning.

Next, an AlGaAs layer was crystal-grown at the GaAs layer by the MOCVD method. A growth temperature of the AlGaAs layer was 600° C. In crystal growth of the AlGaAs layer, a first gas containing TMG and TMA and a second gas containing TBA were used. A flow rate of the second gas to a flow rate of the first gas was 20. The crystal growth of the AlGaAs layer was performed so that a composition ratio of Al and Ga was 1:1.

Through the above processes, a sample was prepared.

### 5.2. Cross-Section Observation

The above sample was processed with a focused ion beam (FIB) processing apparatus, and then a cross section thereof was observed with a scanning transmission electron microscope (STEM). As the FIB processing apparatus, “Helios” manufactured by FEI Company Japan Ltd. was used. A dose amount of the FIB processing apparatus was 0.7 μs. “Talos” manufactured by Thermo Scientific was used as the STEM. An accelerating voltage of the STEM was 200 kV.

The cross-sectional observation was performed on three regions of the sample, that is, a first region, a second region, and a third region. The first region, the second region, and the third region are regions at different positions in plan view.

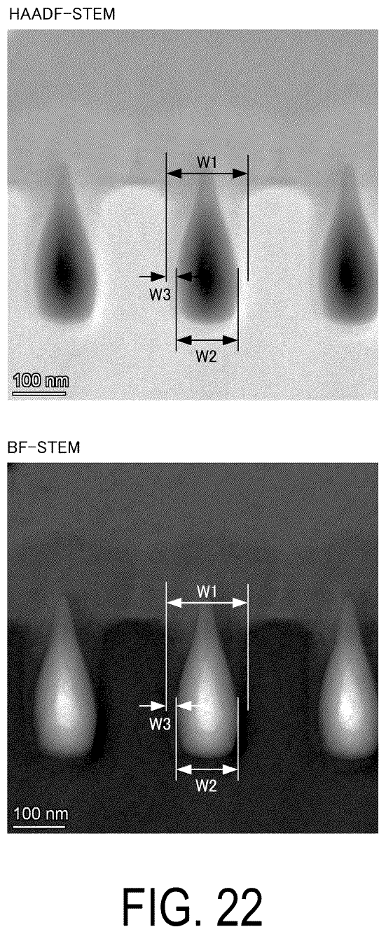

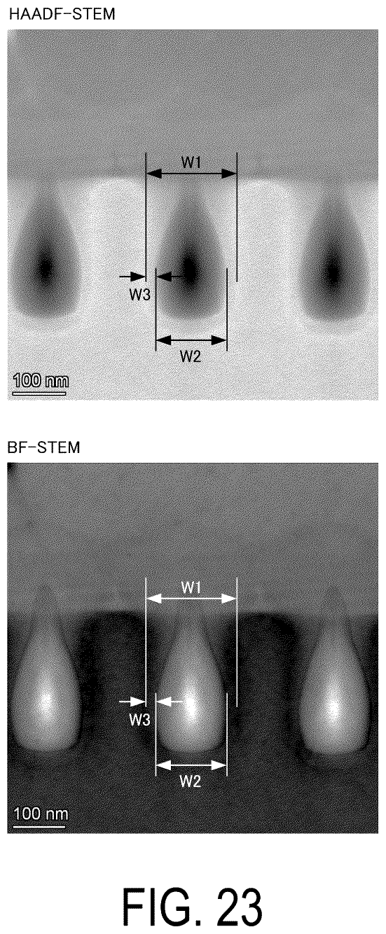

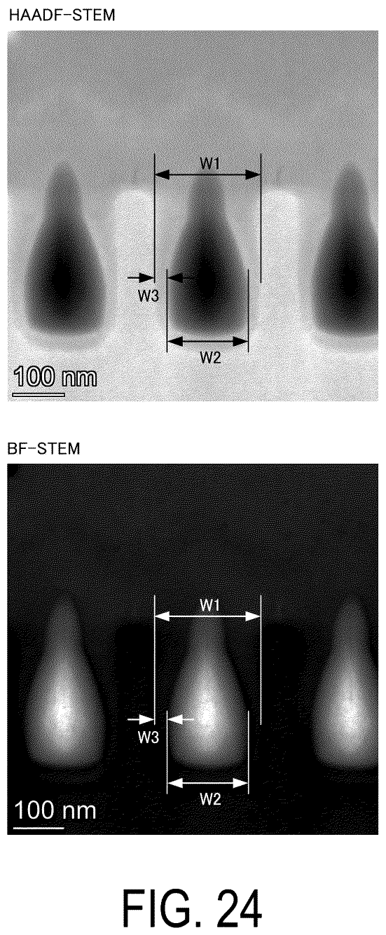

FIG. 22 shows a high-angle annular dark field (HAADF)-STEM image and a bright field (BF)-STEM image of the first region. FIG. 23 shows a HAADF-STEM image and a BF-STEM image of the second region. FIG. 24 shows a HAADF-STEM image and a BF-STEM image of the third region.

As shown in FIG. 22, a void was observed in a hole in the first region. In the first region, a diameter W1 of the hole was 127 mm. A diameter W2 of the void was 91 mm. A pitch of the holes was 261 nm. A thickness W3 of the AlGaAs layer on a side surface of the hole was 18 nm. W3=(W1−W2)/2.

As shown in FIG. 23, a void was observed in a hole in the second region. In the second region, the diameter W1 of the hole was 164 mm. The diameter W2 of the void was 118 mm. The pitch of the holes was 264 nm. The thickness W3 was 23 nm.

As shown in FIG. 24, a void was observed in a hole in the third region. In the third region, the diameter W1 of the hole was 182 mm. The diameter W2 of the void was 133 mm. The pitch of the holes was 264 nm. The thickness W3 was 24.5 nm.

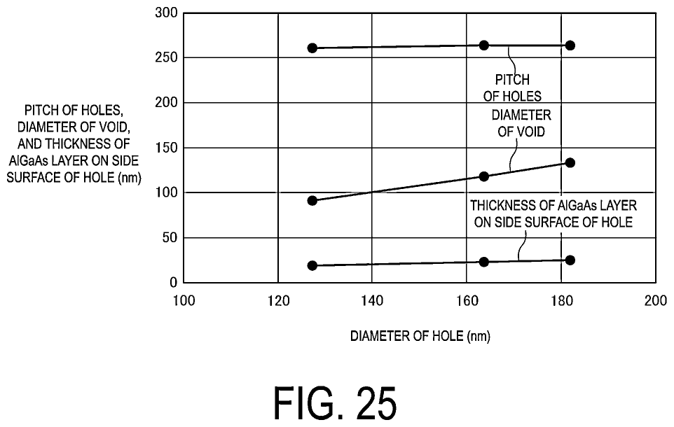

FIG. 25 is a graph showing a relationship between a diameter of the hole, a pitch of the hole, a diameter of the void, and a thickness of the AlGaAs layer on a side surface of the hole in the first region, the second region, and the third region.

As illustrated in FIGS. 22 to 25, the thickness W3 of the AlGaAs layer on the side surface of the hole increases as the diameter W1 of the hole increases. Therefore, it was found that a shadow effect can be exhibited by the crystal growth of the AlGaAs layer shown in the experimental example. There was little change in the pitch of the holes in the first region, the second region, and the third region.

The embodiment and the modification examples described above are merely examples, and are not intended as limiting. For example, each embodiment and each modification example can also be combined together as appropriate.

The present disclosure includes configurations that are substantially identical to the configurations described in the embodiment, for example, configurations with identical functions, methods and results, or with identical advantages and effects. Also, the present disclosure includes configurations obtained by replacing non-essential portions of the configurations described in the embodiment. For example, a material containing GaN may be crystallized on a GaN substrate to form the first semiconductor layer 20, the light-emitting layer 30, the first layer 42, the second layer 44, and the second semiconductor layer 70 made of the material containing GaN. In addition, the present disclosure also includes configurations that achieve the same effects as the configurations described in the embodiments or configurations that can achieve the same advantages.

Further, the present disclosure includes configurations obtained by adding known techniques to the configurations described in the embodiment.

The following contents are derived from the embodiment and the modification examples described above.

An aspect of a method of manufacturing a photonic crystal includes forming a first layer, forming, in the first layer, a first hole, a second hole separated from the first hole by a first distance in a first direction, a third hole separated from the first hole by a second distance larger than the first distance in a second direction intersecting the first direction, and a fourth hole separated from the third hole by a third distance smaller than the second distance in the first direction, and crystal-growing a second layer in the first hole, the second hole, the third hole, and the fourth hole to form a first low refractive index portion having a lower refractive index than the first layer in the first hole, form a second low refractive index portion having a lower refractive index than the first layer in the second hole, form a third low refractive index portion having a lower refractive index than the first layer in the third hole, and form a fourth low refractive index portion having a lower refractive index than the first layer in the fourth hole, wherein in the forming of the first hole, the second hole, the third hole, and the fourth hole, the first hole and the third hole are formed so that a diameter of the first hole is larger than that of the third hole, and the second hole and the fourth hole are formed so that a diameter of the second hole is larger than that of the fourth hole, and in the forming of the first low refractive index portion, the second low refractive index portion, the third low refractive index portion, and the fourth low refractive index portion, the second layer is crystal-grown so that a difference between the diameter of the first hole and a diameter of the first low refractive index portion is larger than a difference between the diameter of the third hole and a diameter of the third low refractive index portion, and a difference between the diameter of the second hole and a diameter of the second low refractive index portion is larger than a difference between the diameter of the fourth hole and a diameter of the fourth low refractive index portion.

According to this method of manufacturing the photonic crystal, a photonic crystal configured to exhibit a stable optical confinement effect can be manufactured.

In one aspect of the method of manufacturing a photonic crystal,
the diameter of the first hole may be smaller than the diameter of the second hole, and the diameter of the third hole may be smaller than the diameter of the fourth hole.

According to this method of manufacturing a photonic crystal, it is possible to increase the asymmetry in the unit lattice and strengthen the radiation of light in a vertical direction.

In an aspect of the method of manufacturing a photonic crystal, the first low refractive index portion and the second low refractive index portion may form a first pair, the third low refractive index portion and the fourth low refractive index portion may form a second pair, and the first pair and the second pair may form a unit lattice.

According to this method of manufacturing a photonic crystal, a photonic crystal having a double unit lattice can be formed.

In an aspect of the method of manufacturing the photonic crystal, a refractive index of the first layer and a refractive index of the second layer may be different from each other.

According to this method of manufacturing the photonic crystal, it is easy to adjust a refractive index of the photonic crystal.

In an aspect of the method of manufacturing the photonic crystal, the second layer may be crystal-grown by an MOCVD method.

According to this method of manufacturing the photonic crystal, the shadow effect can be exhibited in the crystal growth of the second layer.

In an aspect of the method of manufacturing the photonic crystal, a growth temperature of the second layer may be from 550° C. to 650° C.

According to this method of manufacturing the photonic crystal, the shadow effect can be exhibited in the crystal growth of the second layer.

In an aspect of the method of manufacturing the photonic crystal, the second layer is a group III-V semiconductor layer, and in the crystal growth of the second layer, a ratio of a flow rate of a second gas for supplying a group V element to a flow rate of a first gas for supplying a group III element may be from 10 to 30.

According to this method of manufacturing the photonic crystal, the shadow effect can be exhibited in the crystal growth of the second layer.

In an aspect of the method of manufacturing a photonic crystal, the first low refractive index portion, the second low refractive index portion, the third low refractive index portion, and the fourth low refractive index portion may be voids.

According to this method of manufacturing a photonic crystal, it is possible to reduce the refractive index of the first low refractive index portion, the refractive index of the second low refractive index portion, the refractive index of the third low refractive index portion, and the refractive index of the fourth low refractive index portion.

In an aspect of the method of manufacturing a photonic crystal,
in the crystal growth of the second layer, upper sides of the first hole, the second hole, the third hole, and the fourth hole are blocked by the second layer, so that the first gas and the second gas are not supplied to the first hole, the second hole, the third hole, and the fourth hole, and the voids are formed, the upper side of the first hole is blocked later than the upper side of the third hole, and the upper side of the second hole is blocked later than the upper side of the fourth hole.

According to this method of manufacturing a photonic crystal, it is possible to make the difference between the diameter of the first hole and the diameter of the first low refractive index portion larger than the difference between the diameter of the third hole and the diameter of the third low refractive index portion. Further, it is possible to make the difference between the diameter of the second hole and the diameter of the second low refractive index portion larger than the difference between the diameter of the fourth hole and the diameter of the fourth low refractive index portion.

An aspect of a method of manufacturing a light-emitting device includes an aspect of the method of manufacturing the photonic crystal.

According to the method of manufacturing the light-emitting device, it is possible to reduce variations in a threshold current density.

What is claimed is:

1. A method of manufacturing a photonic crystal, the method comprising:
forming a first layer;
forming, in the first layer, a first hole, a second hole separated from the first hole by a first distance in a first direction, a third hole separated from the first hole by a second distance larger than the first distance in a second direction intersecting the first direction, and a fourth hole separated from the third hole by a third distance smaller than the second distance in the first direction; and
crystal-growing a second layer in the first hole, the second hole, the third hole, and the fourth hole to form a first low refractive index portion having a lower refractive index than the first layer in the first hole, form a second low refractive index portion having a lower refractive index than the first layer in the second hole, form a third low refractive index portion having a lower refractive index than the first layer in the third hole, and form a fourth low refractive index portion having a lower refractive index than the first layer in the fourth hole, wherein
in the forming of the first hole, the second hole, the third hole, and the fourth hole,
the first hole and the third hole are formed so that a diameter of the first hole is larger than that of the third hole, and
the second hole and the fourth hole are formed so that a diameter of the second hole is larger than that of the fourth hole, and
in the forming of the first low refractive index portion, the second low refractive index portion, the third low refractive index portion, and the fourth low refractive index portion,
the second layer is crystal-grown so that a difference between the diameter of the first hole and a diameter of the first low refractive index portion is larger than a difference between the diameter of the third hole and a diameter of the third low refractive index portion, and a difference between the diameter of the second hole and a diameter of the second low refractive index portion is larger than a difference between the diameter of the fourth hole and a diameter of the fourth low refractive index portion.

2. The method of manufacturing a photonic crystal according to claim 1, wherein
the diameter of the first hole is smaller than that of the second hole, and
the diameter of the third hole is smaller than that of the fourth hole.

3. The method of manufacturing a photonic crystal according to claim 1, wherein
the first low refractive index portion and the second low refractive index portion form a first pair,
the third low refractive index portion and the fourth low refractive index portion form a second pair, and
the first pair and the second pair form a unit lattice.

4. The method of manufacturing a photonic crystal according to claim 1, wherein
the refractive index of the first layer and the refractive index of the second layer are different from each other.

5. The method of manufacturing a photonic crystal according to claim 1, wherein
the second layer is crystal-grown by a MOCVD method.

6. The method of manufacturing a photonic crystal according to claim 5, wherein
a growth temperature of the second layer is 550° C. or more and 650° C. or less.

7. The method of manufacturing a photonic crystal according to claim 6, wherein
the second layer is a group III-V semiconductor layer, and a ratio of a flow rate of a second gas supplying a group V element to a flow rate of a first gas supplying a group III element in the crystal growth of the second layer is 10 or more and 30 or less.

8. The method of manufacturing a photonic crystal according to claim 7, wherein
the first low refractive index portion, the second low refractive index portion, the third low refractive index portion, and the fourth low refractive index portion are voids.

9. The method of manufacturing a photonic crystal according to claim 8, wherein
in the crystal growth of the second layer, upper sides of the first hole, the second hole, the third hole, and the fourth hole are blocked by the second layer, so that the first gas and the second gas are not supplied to the first hole, the second hole, the third hole, and the fourth hole, and then the voids are formed,
wherein the upper side of the first hole is blocked later than the upper side of the third hole, and the upper side of the second hole is blocked later than the upper side of the fourth hole.

10. A method of manufacturing a light-emitting device comprising the method of manufacturing a photonic crystal according to claim 1.
